(19) United States
(12) Patent Application Publication
(10) Pub. No.: US 2020/0118810 A1
(43) Pub. Date: Apr. 16, 2020

(54) LAMINAR FLOW DEVICE

(71) Applicant: NATIONAL TAIPEI UNIVERSITY OF TECHNOLOGY, Taipei City (TW)

(72) Inventors: SHIH-CHENG HU, Taipei City (TW); TI LIN, Taipei City (TW)

(21) Appl. No.: 16/237,733

(22) Filed: Jan. 1, 2019

(30) Foreign Application Priority Data
Oct. 12, 2018 (TW) 107135885

(51) Int. Cl. H01L 21/02; H01L 21/67; H01L 21/673

(52) U.S. Cl. CPC H01L 21/02057; H01L 21/67017; H01L 21/67772; H01L 21/673; H01L 21/02082

(57) ABSTRACT

The present invention discloses a laminar flow device comprising a U-shaped structure, a side cover, an upper cover, at least one air inlet, and at least one ventilation board. The U-shaped structure is composed of three planer boards. The side cover is disposed at the opening of the U-shaped structure, and combined with the U-shaped structure to form a main body which is open above and below. The upper cover is disposed on the above of main body. The at least one air inlet is disposed on the main for filling a clean gas. The at least one breathable board including a plurality of holes for generating a laminar flow is disposed in the main body.

### TECHNICAL FIELD

The present invention relates to a laminar flow device capable of generating a uniform airflow, particularly, to a laminar flow device arranged between a wafer transfer box and a manufacturing process environment to prevent external pollutants from entering the wafer transfer box.

### BACKGROUND OF RELATED ARTS

In the semiconductor manufacturing process, wafer is a kind of high precision semiconductor material used for manufacturing integrated circuits. Surface of the wafer must be kept clean and not contacted to water, particles or other gaseous pollutants. Therefore, wafers should be placed in a wafer transfer box on various process equipment, so that the wafers in the box do not be contaminated by the pollutants.

Referring to FIG. 1, it illustrates a schematic diagram of a conventional wafer transfer box and a manufacturing process environment. As shown in FIG. 1, the wafer transfer box 7 is usually placed in the manufacturing process environment. When the wafer 70 in the box 7 needs to be removed and the opening 72 of the wafer transfer box 7 is then opened, the pollutants 80 with lower cleanliness level in the manufacturing process environment will invade the wafer transfer box 7 along with laminar flow, and thereby causing the surface contamination damage of the wafer 70 and affecting its quality yield. In order to avoid the external pollutants 80 contaminating the internal wafer 70 when open the opening 82 of the wafer transfer box 7 or the opening between the wafer transfer box 7 and the manufacturing process environment, a device is set between the wafer transfer box 7 and the manufacturing process environment which can produce uniform air flow to enhance the pollutants separate effect.

### SUMMARY

To resolve the drawbacks of the prior arts, the present invention discloses a laminar flow device, comprising: a U-shaped structure, which is composed of three planar boards; a side cover, which is arranged at an opening of the U-shaped structure, wherein the side cover is combined with the U-shaped structure to form a main body which is open above and below thereof; a upper cover arranged on a top of the main body; at least one air inlet arranged on the main body to fill clean a gas; and at least one ventilation board arranged inside the main body, wherein the at least one ventilation board has plural holes to generate a uniform laminar flow.

Further, a material of the ventilation board is a sintered polymer material with a water absorption rate 0.1-5%.

Furthermore. the U-shaped structure is an integrally formed structure, or can be combined with corresponding screw holes and screwing member, or can be mutually gluing, engaging or pressing to form the U-shaped structure. The side cover and the U-shaped structure may be locked by combining the screwing member with the corresponding screw holes.

Embodiments of the invention are illustrated by way of example, and not by way of limitation, in the figures of the accompanying drawings in which like reference numerals refer to similar elements.

### BRIEF DESCRIPTION OF THE DRAWINGS

FIG. 1 is a schematic diagram of a conventional wafer transfer box and a manufacturing process environment.

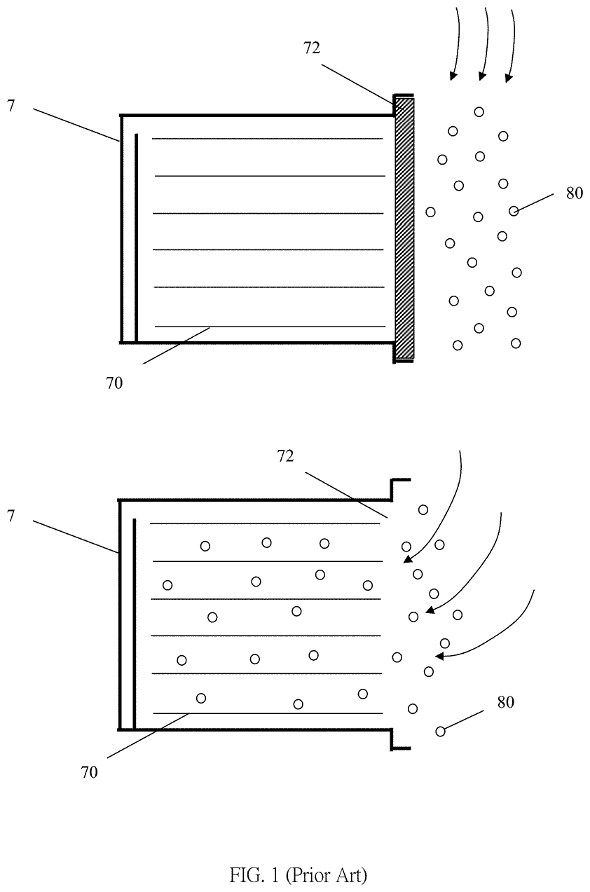

FIG. 2 is a schematic diagram of a laminar flow device according to a preferred embodiment of the present invention.

FIG. 3 is a schematic diagram of a laminar flow device according to another preferred embodiment of the present invention.

FIG. 4 is a schematic diagram of a laminar flow device according to yet another preferred embodiment of the present invention.

FIG. 5 is a schematic diagram of a ventilation board of a preferred embodiment of the present invention.

FIG. 6 illustrates a uniform laminar airflow effect of the laminar flow device of the present invention.

### DETAILED DESCRIPTION OF THE INVENTION

In order to understand the technical features and practical efficacy of the present invention and to implement it in accordance with the contents of the specification, hereinafter, preferred embodiments of the present invention will be described in detail with reference to the accompanying drawings.

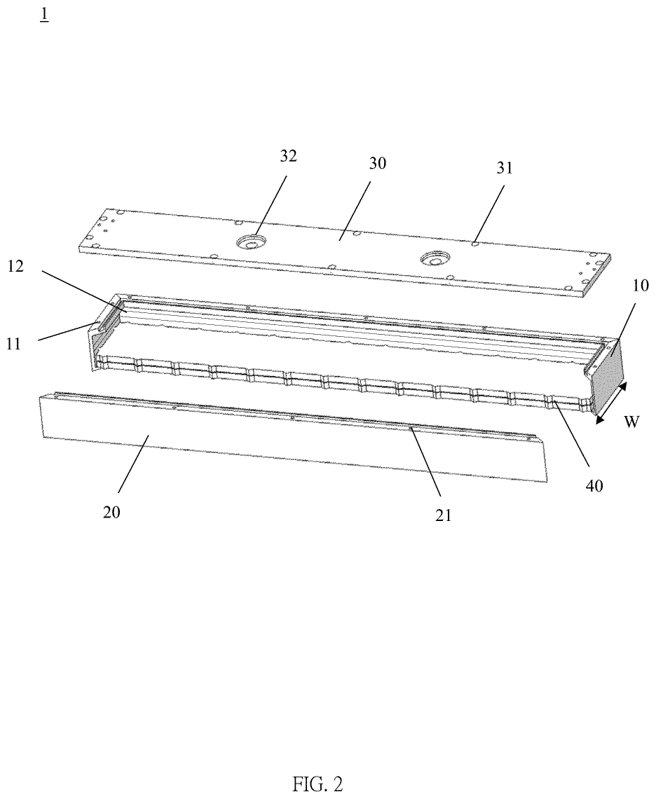

Firstly, referring to FIG. 2, it illustrates a schematic diagram of a laminar flow device according to a preferred embodiment of the present invention. The laminar flow device 1 of the present embodiment comprises: a U-shaped structure 10, which is composed of three long strip planar boards; a side cover 20, which is arranged at the front end opening of the U-shaped structure 10, and the side cover 20 is combined with the U-shaped structure 10 to form a main body which is open above and below thereof; a upper cover 30 arranged on the top of the main body; at least one air inlet 32 arranged on the main body, and the at least one air inlet 32 used to fill a clean gas; and at least one ventilation board 40 arranged inside the main body, and the at least one ventilation board 40 has plural holes, so that the clean gas can penetrate through the plural holes of the at least one ventilation board to generate a uniform air flow below the main body.

In one embodiment, the three long strip planar boards of the U-shaped structure 10 can be an integrally formed structure, or can be combined with the screwing member (not shown) through corresponding screw holes 11, or can be mutually gluing, engaging or pressing to form the U-shaped structure 10 of the present embodiment.

The side cover 20 and the U-shaped structure 10 may also be an integrally formed structure, or the main body of the present embodiment may be formed by combining the screwing member with the corresponding screw holes 11, 21 or by mutually gluing, engaging or pressing with each other.

The main body and the upper cover 30 can also be locked through the corresponding plural screw holes 11, 21, 31 and the screwing members, so that the main body and the upper cover 30 can be locked, and the main body and the upper cover 30 can also be fixed through the above mutually gluing, engaging or pressing.

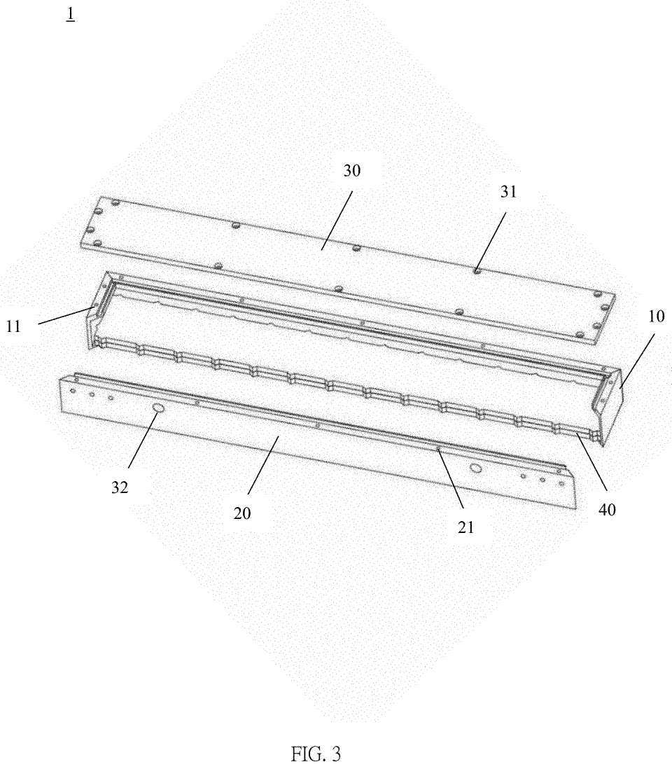

In this embodiment, the at least one air inlet 32 is positioned on the upper cover 30 of the main body and a clean gas is filled into the at least one air inlet 32 of the upper cover 30. In another implementation mode, the position of the at least one air inlet 32 can also be positioned on the side cover 20 (shown in FIG. 3) and a clean gas is filled into the at least one air inlet 32 of the side cover 20 to form side blowing. The specific set position of the at least one air inlet 32 of the invention can be adjusted according to the blowing demand, and the invention is not limited thereto.

In the present embodiment, the inner surface of the U-shaped structure 10 and the side cover 20 also have at least one corresponding transverse groove 12. The at least one ventilation board 40 is configured to fix in at least one circular groove formed by connecting the transverse groove 12 of the inner surface of the U-shaped structure 10 and the side cover 20. The width of each transverse groove 12 is slightly larger than the thickness of the ventilation board. The key point of this structure design is that when the user wants to replace the ventilation board 40 with different pore sizes, he only needs to remove the side cover 20 located in front of the main body, and fix the ventilation board 40 to the transverse groove 12 of the inner surface of the U-shaped structure 10, and then correspond the transverse groove of the inner surface of the side cover 20 to engage the ventilation board 40.

For the method of the ventilation board 40 fixing to the main body, the ventilation board 40 may be fixed to at least one circular groove formed by connecting the at least one transverse groove 12 of the inner surface of the U-shaped structure 10 and the side cover 20, and the ventilation board 40 can also be directly fixed to the inner of the main body of the laminar flow device 1 by gluing.

In this embodiment, the thickness of the ventilation board 40 is between 3 and 10 millimeters (e.g. 5 mm), and a material of the ventilation board 40 is a hydrophobic sintered polymer material with water absorption rate 0.1-5%. The sintered polymer material can be ultra-high-molecular-weight-polyethylene (UPE), high-molecular-polyethylene. Ultra-high-molecular-weight polyethylene (UPE) has the properties including: high toughness and impact resistance, as well as corrosion resistance, chemical resistance, very low friction coefficient, and surface with water absorbability. The contact angle of water on the surface of the ventilation board is between 100 degrees and 130 degrees (e.g. 113 degrees), and there is no sliding angle (no sliding of rotating water beads within 360 degrees).

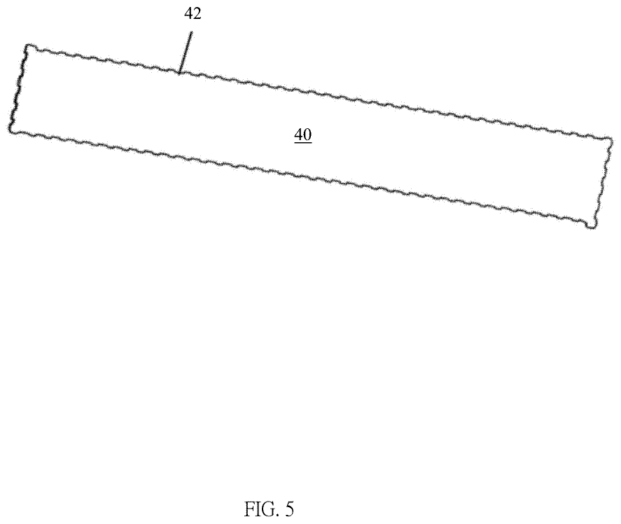

Furthermore, the pore size of the plural holes of the ventilation board 40 is between 0.01 and 100 microns (e.g. between 0.01 and 15 microns), and an edge of the ventilation board 40 has at least one concave-convex structure 42 (shown in FIG. 5) to form a sawtooth-shaped edge of the ventilation board 40. The sawtooth-shaped edge can make the ventilation board 40 to bond with the main body or the circular groove such that the ventilation board 40 is positioned in the main body or the circular groove, and the contact surface between the ventilation board 40 and the adhesive material is increased to enable it to bond more firmly.

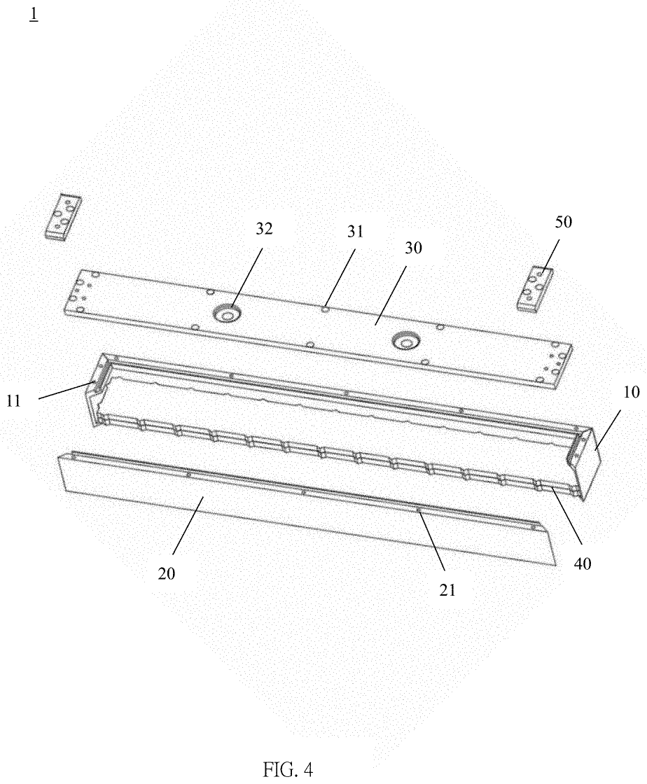

In addition, please refer to FIG. 4, it illustrates a schematic diagram of a laminar flow device according to another preferred embodiment of the present invention. The difference between the laminar flow device 1 of this embodiment and that of the FIG. 2 is that the upper cover of the laminar flow device 1 can also have at least one fixture 50. The at least one fixture 50 and the upper cover 30 can be an integrally formed structure, or can be dismounted through a locking fixture and corresponding screw holes, or can be glued, engaged or pressed together to fix each other. The purpose of the at least one fixture 50 is that the laminar flow device 1 may be fixed on a specific location, such as a process opening or a valve.

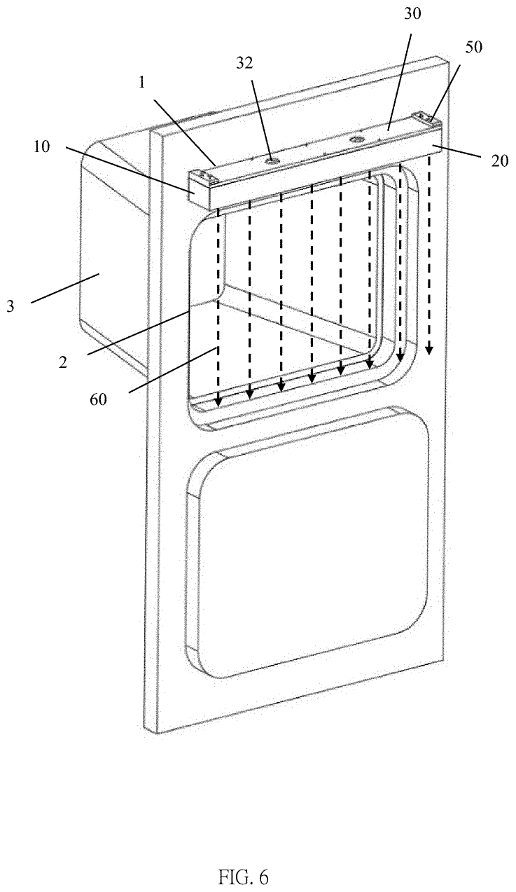

Please refer to FIG. 6, it illustrates a uniform laminar airflow effect of the laminar flow device of the present invention. The laminar flow device 1 of the invention is installed above the opening 2 through at least one fixture 50 as the process needs to be converted, and a clean gas, such as a clean dry air (CDA) or an inert gas can be filled into the main body from the air inlet 32 which can be configured with an intake valve and a flow regulating device (not shown). When the clean gas is filled into the main body from the air inlets 32 of the top cover 30 or side cover (refer to FIG. 3) wherein the air inlets 32 is installed with an intake valve, the pressure resistance is formed inside the main body due to gas resistance created by the extremely small holes (porosity) of the ventilation board 40 (refer to FIG. 2). Until the internal pressure inside the main body reaches a certain level (maximum static pressure), the gas will pass through the plural holes of the ventilation board 40 after gas regulating, and followed by draining downward from the open area (i.e. gas outlet) below the main body. Finally, a uniform flow 60 is generated at the opening 2 in which the wafer transfer box 3 connected with the process environment to prevent external pollutants (such as water, particulates, etc.) from entering the wafer transfer box 3 when the wafer is taken out (i.e. when the opening 2 is opened) to avoid polluting inside of the wafer transfer box 3.

The outlet width of the uniform airflow 60 is determined by the area of the main body or the ventilation board 40. If the area is too small, the airflow may not be easily concentrated and cannot blow to the bottom of the wafer transfer box 3. If the area is too large, the unnecessary gas will be consumed. Therefore, referring to FIG. 2, the main body of the laminar flow device 1 of the present invention can have a width of between 10-100 millimeter (e.g. 70 mm) and a diameter of an air inlet 32 between 6-15 millimeter (e.g. 8 mm).

The internal pressure resistance of the main body depends on the number of the ventilation board 40 and the size of the permeable pore of the ventilation board 40. The pore size of each the ventilation board 40 in the laminar flow device 1 of the present invention is 0.01 to 100 microns (m) to achieve gas rectification and uniform gas drain. If the pore size is too large, it can not achieve the effects of rectification and uniform airflow due to insufficient pressure resistance; if the pore size is too small, it may lead to clean dry air or inert gas incapable of flowing out due to excessive internal pressure resistance.

The airflow generated by the laminar flow device of the present invention has Reynolds number between 1000 and 2000 (average flow velocity between 0.25-0.35 meter/second, hydraulic diameter (generally characteristic length) between 7-9 centimeter) and the outlet airflow is uniform laminar flow (Laminar Flow), which can prevent any pollutants, such as water gas, ammonia gas (NH₃), or particulates such as chlorine (Cl₂), hydrofluoric acid (HF) or hydrochloric acid (HCl) from entering inside of the wafer transfer box. Combining with the existing wafer transfer box clean system, the possibility of external pollutants intruding into the wafer transfer box is greatly reduced when the wafer is picked or placed (open the opening).

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A laminar flow device, comprising:
a U-shaped structure, which is composed of three planar boards;
a side cover, which is arranged at an opening of said U-shaped structure, wherein said side cover is combined with said U-shaped structure to form a main body which is open above and below thereof;
an upper cover arranged on a top of said main body;
at least one air inlet arranged on said main body to fill clean a gas; and
at least one ventilation board arranged inside said main body, wherein said at least one ventilation board has plural holes to generate a uniform laminar flow;
wherein a material of said ventilation board is a sintered polymer material with a water absorption rate 0.1-5%.

2. The device of claim 1, wherein said U-shaped structure is an integrally formed structure.

3. The device of claim 1, wherein said main body and said upper cover is locked through corresponding plural screw holes.

4. The device of claim 1, wherein a pore size of said plural holes is between 0.01 and 15 microns.

5. The device of claim 1, wherein an inner surface of said U-shaped structure and said side cover have at least one corresponding transverse groove.

6. The device of claim 5, wherein said at least one ventilation board is configured in at least one circular groove formed by connecting said transverse groove of said inner surface of said U-shaped structure and said side cover.

7. The device of claim 1, wherein an edge of said ventilation board has at least one concave-convex structure.

8. The device of claim 1, wherein said clean gas is a clean dry air or an inert gas.

9. The device of claim 1, wherein Reynolds number of said uniform laminar flow is between 1000 and 2000.

10. The device of claim 1, wherein said main body includes a dismounted locking fixture.
